(19) United States
(12) Patent Application Publication
(10) Pub. No.: US 2004/0079549 A1
(43) Pub. Date: Apr. 29, 2004

(54) Conductive substrate structure

(76) Inventor: Yuan Liang Yu, Taoyuan City (TW)

Correspondence Address: BROWDY AND NEIMARK, P.L.L.C., 624 NINTH STREET, NW, SUITE 300, WASHINGTON, DC, 20001-5303, US

(21) Appl. No.: 10/282,079

(22) Filed: Oct. 29, 2002

(51) Int. Cl. H05K 1/03

(52) U.S. Cl. 174/255

(57) ABSTRACT

A substrate structure that is conductive after attachment comprises a lower substrate, an upper substrate, and an adhesive. The upper and lower substrates are made of metal. A plurality of contacts are formed on a bottom surface of the upper substrate. The adhesive is applied between a top surface of the lower substrate and a bottom surface of the upper substrate to bond the upper and lower substrates, while the contacts on the bottom surface of the upper substrate being electrically connected to the top surface of the lower substrate. There is no insulation between the bonding portion, the upper substrate and the lower substrate so that good shielding is thereby provided.

### BACKGROUND OF THE INVENTION

1. Field of the Invention

The invention relates to a substrate structure that is conductive after attachment. More specifically, to a substrate structure suitable for an electronic product, in which an upper substrate and a lower substrate are electrically connected after having been bonded to provide good shielding.

2. Description of the Related Art

As the electronic industry advances, the manufactured electronic products become increasingly thinner. These electronic products usually comprise inner substrates the thickness of which is also reduced. The substrate is usually made of metal and has a good strength characteristic. Usually, a plurality of bolts are used to connect the substrate to electronic parts such as a motherboard. FIG. 1 is an exploded view of a bolt 20a and a substrate 10a.

A method known in the prior art for bonding a bolt 20a and a substrate 10a includes thermally bonding and welding. In FIG. 2, the bolt 20a and the substrate 10a, made of the same material, are melted together by heating. However, this may form protuberances on an external surface of the substrate 10a. The resulting uneven surface of the substrate 10a needs to be smoothened in an additional process.

In FIG. 3, a lower end of the bolt 20a is welded onto the substrate 10a. Since the welding method also requires a high temperature process, it therefore causes the same disadvantages as recited above. This method is only used in processing a thick board in which the board surface is not critical and a surface treatment is not required.

FIG. 4 and FIG. 5 illustrate another substrate structure including a lower substrate 30a, an upper substrate 40a, and a bonding portion 50a. The lower substrate 30a is made of metal. The bonding portion 50a and the upper substrate 40a are also made of metal. The upper substrate 40a is connected to a lower side of the bonding portion 50a. An adhesive 60a is applied between a top surface of the lower substrate 30a and a bottom surface of the upper substrate 40a. Thereby, the bonding between the upper and lower substrates are enhanced without any undesired irregularities.

However, the adhesive 60a between the top surface of the lower substrate 30a and the bottom surface of the upper substrate 40a is insulating, resulting in the insulation between the upper and lower substrates 40a, 30a. Since there is no electrical connection between the upper and lower substrates 40a, 30a, an electromagnetic interference (EMI) test is not successful.

Therefore, the conventional substrate structure is not practically satisfactory.

### SUMMARY OF THE INVENTION

It is one object of the invention to provide a substrate structure that is conductive after attachment. A plurality of contacts are formed on a bottom surface of an upper substrate. The contacts penetrate through an adhesive between the upper substrate and a lower substrate to electrically connect the upper and lower substrates. There is no insulation between the bonding portion, the upper substrate and the lower substrate so that EMI test is passed and good shielding is thereby provided.

In order to achieve the above and other objectives of the invention, a substrate structure comprising a lower substrate, an upper substrate and an adhesive is provided. The upper and lower substrates are made of metal. A plurality of contacts are formed on a bottom surface of the upper substrate. The adhesive is applied between a top surface of the lower substrate and a bottom surface of the upper substrate to bond the upper and lower substrates, while the contacts on the bottom surface of the upper substrate being electrically connected to the top surface of the lower substrate.

To provide a further understanding of the invention, the following detailed description illustrates embodiments and examples of the invention, this detailed description being provided only for illustration of the invention.

### BRIEF DESCRIPTION OF THE DRAWINGS

The drawings included herein provide a further understanding of the invention. A brief introduction of the drawings is as follows:

FIG. 1 is a perspective view of a conventional substrate structure;

FIG. 2 is a cross-sectional view of a conventional substrate structure;

FIG. 3 is a cross-sectional view of another conventional substrate structure;

FIG. 4 is an exploded view of still another conventional substrate structure;

FIG. 5 is a cross-sectional view of still another conventional substrate structure;

FIG. 6 is an exploded view of a substrate structure according to a first embodiment of the invention;

FIG. 7 is a cross-sectional view of a substrate structure according to the first embodiment of the invention;

FIG. 8 is an exploded view of a substrate structure according to a second embodiment of the invention;

FIG. 9 is an exploded view of a substrate structure according to a third embodiment of the invention;

FIG. 10 is an exploded view of a substrate structure according to a fourth embodiment of the invention; and

FIG. 11 is a perspective view of a substrate structure according to a fifth embodiment of the invention.

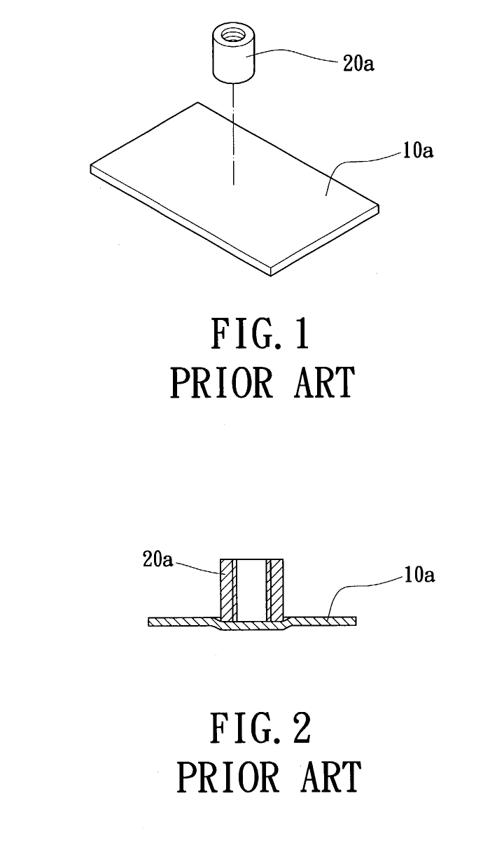

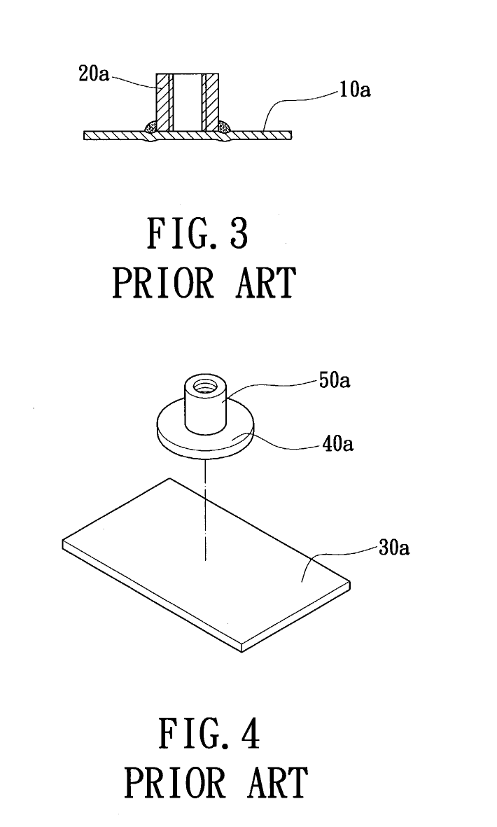

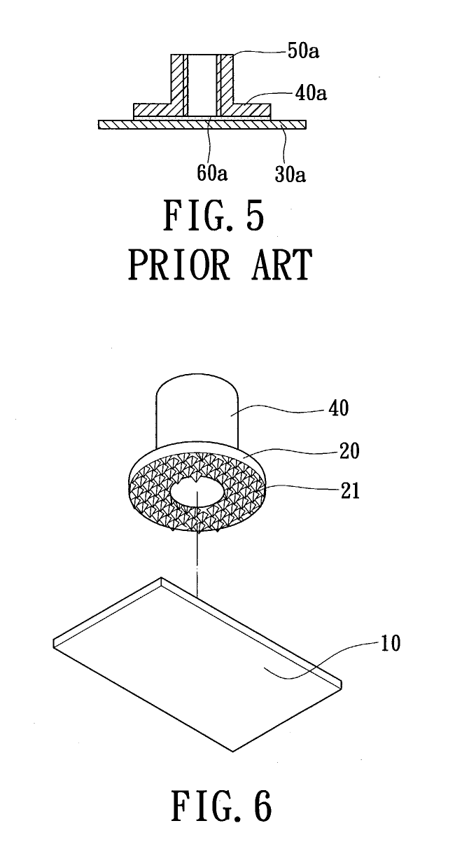

### DETAILED DESCRIPTION OF THE EMBODIMENTS

Wherever possible in the following description, like reference numerals will refer to like elements and parts unless otherwise illustrated.

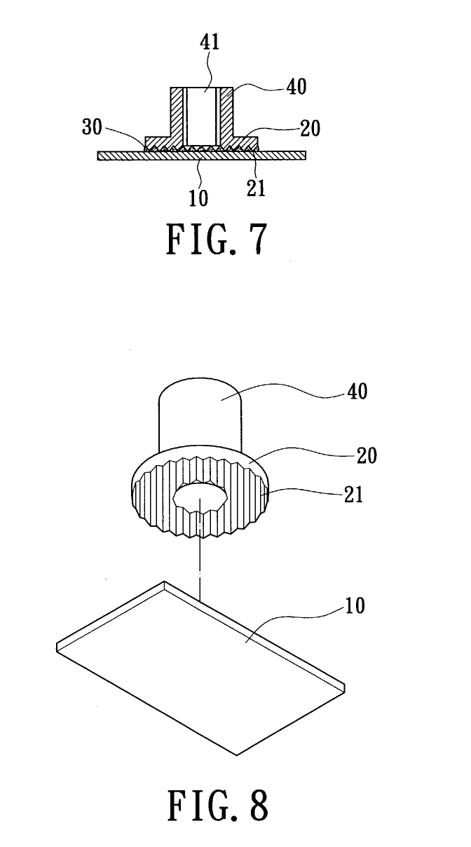

Referring to FIG. 6 and FIG. 7, the invention provides a substrate structure that is conductive and is bonded by an adhesive. The substrate structure includes a lower substrate 10, an upper substrate 20, and an adhesive 30. The lower substrate 10 is made of metal. An example of the lower substrate 10 includes a board of an electronic product or a base element inside the electronic product.

The upper substrate 20 is arranged above the lower substrate 10 and connected to a bonding portion 40 located above the upper substrate 20. The bonding portion 40 and the upper substrate 20 are also made of metal. More particularly, the upper substrate 20 is connected to a lower side of the bonding portion 40. The bonding portion 40 has a shape that may be, for example, a cylinder or a polygonal column. A screwed hole 41 is formed at a center of the bonding portion 40 to engage with an electronic part on a motherboard. One or 20 more contacts 21 are formed in a manner to protrude from the bottom of the upper substrate 20 in a shape of, for example, dots, lines or matrix. In this embodiment, the contacts 21 are distributed in a shape of dots.

The adhesive 30 is applied on a top of the lower substrate 30 and a bottom of the upper substrate 20 to attach the upper substrate 20 and the bonding portion 40 to the lower substrate 10. Meanwhile, the contacts 21 on the bottom of the upper substrate 20 are connected to the lower substrate 20. With the above configuration, the substrate structure is conductive after the upper and lower substrates have been attached by means of the adhesive.

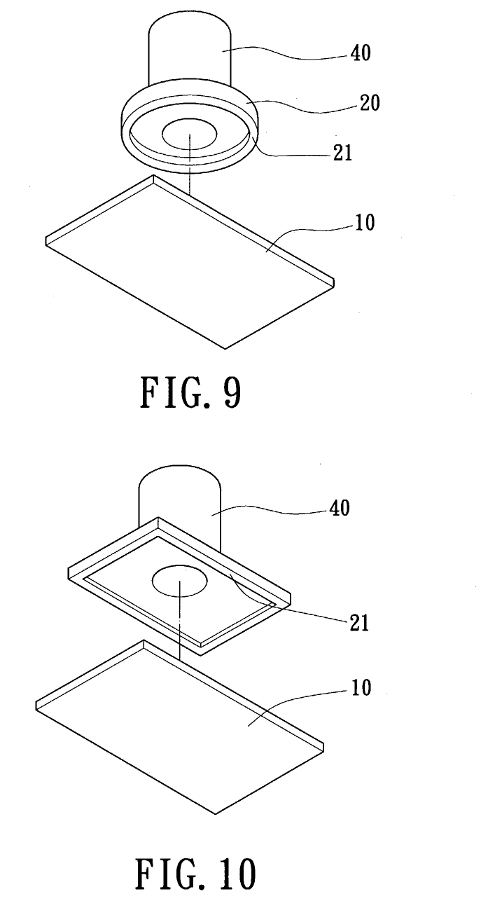

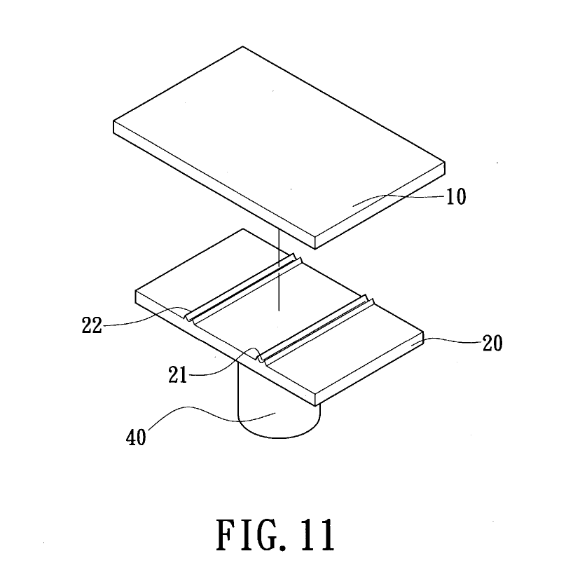

Referring to FIG. 8, a plurality of contacts 21 are formed on the bottom surface of the upper substrate 20 in a shape of lines. In FIG. 9, a plurality of contacts 21 are formed on the bottom surface of the upper substrate 20 in a shape of circles. In FIG. 10, a plurality of contacts 21 are formed on the bottom surface of the upper substrate 20 in a shape of rectangles. In FIG. 11, a plurality of parallel grooves 22 are formed on the bottom surface of the upper substrate 20. A plurality of contacts 21 are formed along edges of each groove 22 on the bottom surface of the upper substrate 20.

By applying the adhesive 30 between the top surface of the lower substrate 10 and the bottom surface of the upper substrate 20, it is easy to fabricate a product that has strong bonding and a smooth surface without additional processing.

One characteristic of the invention therefore includes the formation of a plurality of the contacts 21 on the bottom surface of the upper substrate 20. The contacts 21 penetrate through the adhesive 30 to electrically connect the upper and lower substrate 20, 10. Thereby, there is no insulation between the bonding portion 40, the upper substrate 20 and the lower substrate 10. Therefore, the constructed product can pass the EMI test and good shielding is provided.

Those skilled in the art will readily appreciate that the above description is only illustrative of specific embodiments and examples of the invention. The invention should therefore cover various modifications and variations made to the herein-described structure and operations of the invention, provided they fall within the scope of the invention as defined in the following appended claims.

What is claimed is:

1. A substrate structure being conductive after attachment, the substrate structure comprising:
a lower substrate, made of metal;
an upper substrate, made of metal, a plurality of contacts being formed on a bottom surface thereof; and
an adhesive, applied between a top surface of the lower substrate and a bottom surface of the upper substrate for bonding the upper and lower substrates, while the contacts on the bottom surface of the upper substrate being electrically connected to the top surface of the lower substrate.

2. The substrate structure of claim 1, wherein the contacts are distributed in a shape of dots.

3. The substrate structure of claim 1, wherein the contacts are distributed in a shape of lines.

4. The substrate structure of claim 1, wherein the contacts are distributed in a shape of matrix.

5. The substrate structure of claim 1, wherein the upper substrate is connected to a bonding portion that has a screwed hole.
